(19) United States
(12) Patent Application Publication
(10) Pub. No.: US 2024/0381782 A1
(43) Pub. Date: Nov. 14, 2024

(54) MAGNETORESISTIVE DEVICES AND SEMICONDUCTOR DEVICES

(71) Applicant: Samsung Electronics Co., Ltd., Suwon-si (KR)

(72) Inventors: Namhai PHAM, Tokyo (JP); Hoanghuy HO, Tokyo (JP); Shigeki TAKAHASHI, Yokohama-shi (JP); Yoshiyuki HIRAYAMA, Yokohama-shi (JP)

(73) Assignee: Samsung Electronics Co., Ltd., Suwon-si (KR)

(21) Appl. No.: 18/648,863

(22) Filed: Apr. 29, 2024

(30) Foreign Application Priority Data
May 10, 2023 (JP) 2023-077596
Nov. 24, 2023 (KR) 10-2023-0165280

(51) Int. Cl. H10N 50/80; H10B 61/00; H10N 50/10; H10N 50/85

(52) U.S. Cl. CPC H10N 50/80; H10B 61/00; H10N 50/10; H10N 50/85

(57) ABSTRACT

A magnetoresistive device and a semiconductor device in which magnetic properties may be improved are provided. A magnetoresistive device includes an SOT electrode layer, a metal oxide layer, a first nonmagnetic layer, and a magnetic tunnel junction element including a first magnetic layer, a second nonmagnetic layer, and a second magnetic layer. The SOT electrode layer includes BiSb, the metal oxide layer includes metal oxide, the first nonmagnetic layer at least partially includes an amorphous material, and a crystal included in the SOT electrode layer and a crystal included in the first magnetic layer have different rotational symmetries to a stacking direction thereof.

### CROSS-REFERENCE TO RELATED APPLICATION(S)

This application claims the benefit under 35 USC 119 (a) of Korean Patent Application No. 10-2023-0165280 filed on Nov. 24, 2023 in the Korean Intellectual Property Office and Japanese Patent Application No. 2023-077596 filed on May 10, 2023 in the Japan Patent Office, the entire disclosures of which are incorporated herein by reference for all purposes.

### BACKGROUND

The present inventive concepts relate to magnetoresistive devices and semiconductor devices.

To reduce the switching current of a Spin Orbit Torque (hereinafter referred to as SOT)-Magnetoresistive Random Access Memory (hereinafter referred to as MRAM), it is required to increase a spin Hall angle, a conversion efficiency from current to spin current in the SOT electrode.

For example, by using a SOT electrode in which bismuth antimony (hereinafter referred to as BiSb) of a topological insulator is oriented in a (012) crystal, a technology for significantly increasing a spin Hall angle and reducing a switching current has been proposed.

A configuration of a buffer layer may promote a (012) crystal orientation which may obtain a large spin hole angle in a SOT electrode of BiSb.

By using a SOT electrode of BiSb crystallized in the (012) plane orientation by a Molecular Beam Epitaxy method (hereinafter referred to as the MBE method), significantly large values may be obtained, compared with the case of the related art in which the spin hole angle is 52 and SOT electrodes of heavy metals such as tungsten (hereinafter referred to as W), tantalum (hereinafter referred to as Ta) and the like are used.

Furthermore, results in which spin hole conductivity, as an indicator of power saving, increases by about two orders of magnitude, have been obtained, as compared to the previous cases of W and Ta.

However, it is known that it is difficult to obtain a flat thin film of BiSb in the case of using the sputtering film deposition method more suitable for manufacturing SOT-MRAM. In the case in which a ferromagnetic layer constituting a magnetic tunnel junction (hereinafter referred to as MTJ) device is stacked on a BiSb thin film with reduced flatness, the interface of BiSb/ferromagnetic layer becomes rough. As a result, since spin diffusion loss occurs at the interface of BiSb/ferromagnetic layer, there may be a problem in which the spin Hall angle is significantly reduced.

Furthermore, since a BiSb material has the property of being easy to diffuse, there is a problem of interdiffusion in which Sb in BiSb diffuses into the ferromagnetic layer containing CoPt and the like, even immediately after sputtering film deposition, and conversely, Pt diffuses into the BiSb layer.

Further, since SOT-MRAM generally adopts a stacked structure of SOT electrode/ferromagnetic layer, the switching current flowing through the SOT electrode is shunted to the ferromagnetic layer, and the effective switching current flowing within the SOT electrode decreases. Therefore, there may be a shunt current problem in which a threshold current required for switching increases. As such, there is a desire to improve the magnetic properties and the resilience thereof of magnetoresistive devices.

### SUMMARY

The present inventive concepts are intended to resolve these problems, and according to some aspects of the present inventive concepts, magnetoresistive devices and semiconductor devices in which magnetic properties may be improved are provided.

According to some example embodiments, a magnetoresistive device includes a spin orbit torque (SOT) electrode layer, a metal oxide layer on the SOT electrode layer, a first nonmagnetic layer on the metal oxide layer, and a magnetic tunnel junction element including a first magnetic layer on the first nonmagnetic layer, a second nonmagnetic layer on the first magnetic layer, and a second magnetic layer on the second nonmagnetic layer. The SOT electrode layer including BiSb, the metal oxide layer including metal oxide, the first nonmagnetic layer at least partially including an amorphous material, and a crystal included in the SOT electrode layer and a crystal included in the first magnetic layer have different rotational symmetries to a stacking direction thereof.

The magnetoresistive device may further include a third magnetic layer between the metal oxide layer and the first nonmagnetic layer, and the third magnetic layer may be magnetically coupled to the first magnetic layer.

The magnetoresistive device may further include a third nonmagnetic layer between the metal oxide layer and the third magnetic layer, and the third nonmagnetic layer may have a crystal structure alleviating mismatch between crystal lattices of the metal oxide layer and the third magnetic layer.

The magnetoresistive device may further include a third nonmagnetic layer between the metal oxide layer and the third magnetic layer, and a surface energy of the third magnetic layer on the third nonmagnetic layer is smaller than a surface energy of the third magnetic layer on the metal oxide layer.

The metal oxide layer may include a first metal oxide layer and a second metal oxide layer, and the first metal oxide layer may include a metal oxide different from a metal oxide of the second metal oxide layer.

The metal oxide layer may include a metal oxide having a spin diffusion length longer than a distance between the SOT electrode layer and the first magnetic layer.

The first magnetic layer may include a crystal with a four-fold rotational symmetry, and the SOT layer may include a crystal with three-fold rotational symmetry.

The metal oxide layer may contain Cr₂O₃.

A thickness of the metal oxide layer may be 0.5 nm to 2.5 nm.

The first nonmagnetic layer may at least partially include an amorphous metal.

The first nonmagnetic layer may include at least one of a single transition metal, an alloy of transition metals, a compound of a transition metal and a semimetal, a transition metal nitride, a transition metal oxide, or a B—C—N based material.

A thickness of the first nonmagnetic layer may be 0.8 nm to 1.0 nm.

The third magnetic layer may include at least one of Co or a Co—Pt alloy.

The third magnetic layer may include a crystal with three-fold rotational symmetry with the stacking direction, as the rotation axis.

The third nonmagnetic layer may include a metal.

The third nonmagnetic layer may include TiCr₂.

A thickness of the third nonmagnetic layer may be greater than 0 nm and less than 1.0 nm.

The third nonmagnetic layer may include the crystal with three-fold rotational symmetry with the stacking direction being the rotation axis.

The first metal oxide layer may include Cr₂O₃ as a material, and the second metal oxide layer may include at least one of aluminum oxide, tantalum oxide, magnesium oxide, ruthenium oxide, hafnium oxide, or chromium oxide.

The magnetoresistive device may further include a base layer, and the SOT electrode layer may be on the base layer.

According to some example embodiments, a semiconductor device includes the magnetoresistive device described above.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a cross-sectional view illustrating Embodiment 1 of a magnetoresistive device according to some example embodiments;

FIG. 2 is a cross-sectional view illustrating Embodiment 1 of a magnetoresistive device according to some example embodiments;

FIG. 3 is a cross-sectional view illustrating a magnetoresistive device according to some example embodiments;

FIG. 4 is a cross-sectional view illustrating Embodiment 2 of a magnetoresistive device according to some example embodiments;

FIG. 5 is a cross-sectional view illustrating Embodiment 2 of a magnetoresistive device according to a modified example of some example embodiments;

FIG. 6 is a cross-sectional view illustrating Embodiment 3 of a magnetoresistive device according to some example embodiments;

FIG. 7 is a cross-sectional view illustrating Embodiment 3 of a magnetoresistive device according to a modified example of some example embodiments;

FIG. 8 is a cross-sectional view illustrating Embodiment 4 of a magnetoresistive device according to some example embodiments;

FIG. 9 is a cross-sectional view illustrating Embodiment 4 of a magnetoresistive device according to a modified example of some example embodiments;

FIG. 10 is a circuit diagram illustrating Embodiment 5 of a semiconductor device according to some example embodiments; and

FIG. 11 is a circuit diagram illustrating Embodiment 5 of a semiconductor device according to some example embodiments.

### DETAILED DESCRIPTION

For clarity of descriptions, the following description and drawings are omitted and simplified as appropriate. In addition, in respective drawings, like elements are given the same reference numerals, and duplicate descriptions are omitted when necessary.

### Overview of Example Embodiment

First, an outline of some example embodiments will be described. Spin transfer torque type MRAM (hereinafter referred to as STT-MRAM), currently being widely researched and developed, performs write and read operations for the MTJ element using a two-terminal structure.

For this reason, in the case in which STT-MRAM is highly integrated, there is a problem in which a sufficient read margin cannot be obtained and a sufficiently long thermal disturbance resistance cannot be obtained.

However, SOT-MRAM may not only improves upon these problems but also enables and supports writing at high speed and with low power consumption, and further SOT-MRAM using, for example, a Spin Hall Effect (hereinafter referred to as SHE) may be beneficial. SOT-MRAM has a three-terminal structure generating spin current from current and performing writing. By using a BiSb topological insulator as the material for the SOT electrode of the SOT-MRAM, highly efficient SOT switching may be obtained.

However, in case of using BiSb in the SOT electrode, surface flatness, interdiffusion of constituent elements, shunt current to the ferromagnetic material, and the like may be of concern, and in addition to deteriorating the performance of SOT-MRAM, it was a factor that made practical use difficult.

In the present inventive concepts, in the device structure of SOT-MRAM, a metal oxide capable of propagating a spin current is inserted between an SOT electrode layer of BiSb and a recording layer of the MTJ element thereon. Furthermore, a SOT electrode layer/metal oxide film of BiSb with different crystal systems, and a low-resistance amorphous layer for dividing the crystal structure of the MTJ element containing CoFeB/MgO are inserted. Accordingly, the writing efficiency of the SOT-MRAM is increased and the read efficiency of the MTJ element is improved, thereby providing a SOT-MRAM with good characteristics.

### Embodiment 1

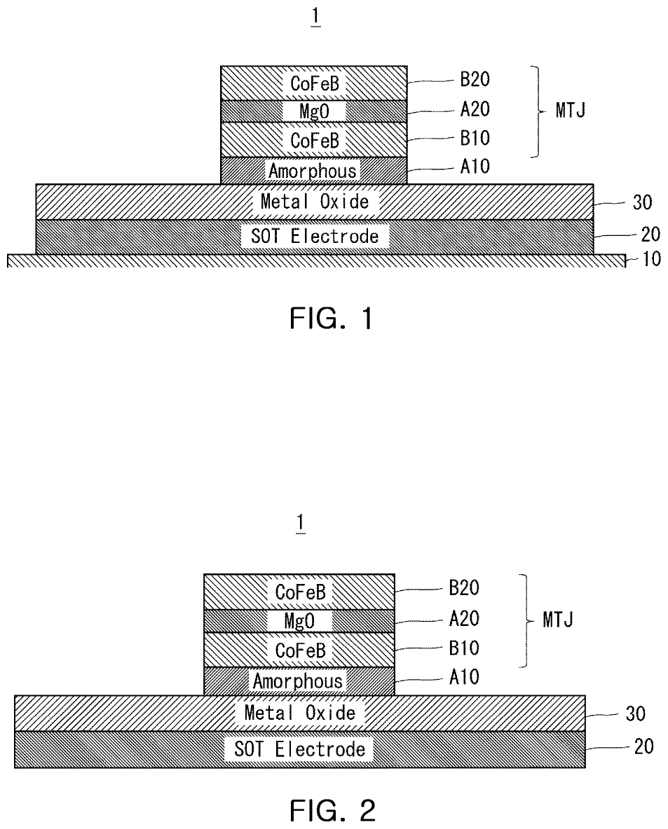

A magnetoresistive device according to Embodiment 1 will be described. FIGS. 1 and 2 are cross-sectional views illustrating Embodiment 1 of a magnetoresistive device according to some example embodiments. As illustrated in FIG. 1, a magnetoresistive device 1 includes a base layer 10, a SOT electrode layer 20, a metal oxide layer 30, a first nonmagnetic layer A10, a first magnetic layer B10, a second nonmagnetic layer A20, and a second magnetic layer B20. In some example embodiments, as illustrated in FIG. 2, in the magnetoresistive device 1, the base layer 10 may be omitted. In the following drawings, the base layer 10 is omitted. In the drawings, for convenience of explanation, materials or names included in respective layers are illustrated, but these materials and names are examples and do not limit the material of respective layers to these materials.

In addition, for convenience of explanation, the metal oxide layer 30 is referred to as a metal oxide 30, and the first nonmagnetic layer A10 is referred to as a first amorphous A10. Additionally, the first magnetic layer B10 is referred to as a first recording layer B10.

The SOT electrode layer 20, the metal oxide layer (metal oxide) 30, the first nonmagnetic layer (amorphous) A10, the first magnetic layer (recording layer) B10, the second nonmagnetic layer A20, and the second magnetic layer B20 may be formed by thin film formation methods such as sputtering, reactive sputtering, MBE, electron beam deposition, and the like, and may also be formed by thin film formation methods other than these. All layers may be formed using a predetermined thin film forming method, and some layers may be formed using a thin film forming method different from the formation methods of other layers.

The first magnetic layer (recording layer) B10, the second nonmagnetic layer A20, and the second magnetic layer B20 constitute an MTJ element. The MTJ element including the first magnetic layer (recording layer) B10, the second nonmagnetic layer A20, and the second magnetic layer B20 may be patterned. In some example embodiments, patterning may be performed on the first nonmagnetic layer (amorphous) A10, the first magnetic layer (recording layer) B10, the second nonmagnetic layer A20, and the second magnetic layer B20.

### <Base Layer>

The base layer 10 includes a layer that serves as a base when forming the SOT electrode layer 20. Additionally, the base layer 10 may be an insulating buffer layer. The base layer 10 includes an insulator such as silicon oxide (SiO₂) or the like, for example. In some example embodiments, the base layer 10 is not limited to including an insulator such as silicon oxide, as long as it is a material that serves as a base in forming the SOT electrode layer 20, and may also contain other materials, such as sapphire or the like.

### <SOT Electrode Layer>

The SOT electrode layer 20 is provided on the base layer 10. The SOT electrode layer 20 is a layer for applying spin-orbit torque to the first magnetic layer (recording layer) B10, which is the recording layer of the MTJ element. For example, by passing a current through the SOT electrode layer 20, a spin-orbit torque may be applied to the first magnetic layer (recording layer) B10 of the MTJ element. The SOT electrode layer 20 contains BiSb as a material. The SOT electrode layer 20 may have a trigonal crystal structure.

The stable structure of BiSb is trigonal, and in a structure in which the (001) plane is oriented on the base layer 10, a relatively large spin Hall angle may be obtained. In this case, the SOT electrode layer 20 has a three-fold rotational symmetry crystal structure with the direction perpendicular to the film surface as the rotation axis. However, a structure in which the (012) plane of BiSb is oriented on the base layer 10 also produces a significantly large spin Hall angle. In this case, because the SOT electrode layer 20 is a face-centered lattice that is rectangular in plan, a structure that has neither 3-fold nor 4-fold rotational symmetry with the vertical direction of the film surface as the axis of rotation is used. In the following, the rotation axis of rotational symmetry is described as the stacking direction of respective layers.

### <Metal Oxide Layer (Metal Oxide)>

A metal oxide layer (metal oxide) 30 is provided on the SOT electrode layer 20. The metal oxide layer (metal oxide) 30 contains metal oxide as a material. The metal oxide layer (metal oxide) 30 includes, for example, a metal oxide of which a spin diffusion length is longer than the device size. For example, the metal oxide layer (metal oxide) 30 includes a metal oxide of which a spin diffusion length is longer than a distance between the SOT electrode layer 20 and the first magnetic layer (recording layer) B10. For example, the metal oxide layer (metal oxide) 30 may contain Cr₂O₃ as a material. In some example embodiments, the metal oxide layer (metal oxide) 30 is not limited to containing Cr₂O₃ as a material. However, when the metal oxide layer (metal oxide) 30 contains Cr₂O₃, the magnetic properties of the magnetoresistive device 1 may be significantly improved. A thickness of the metal oxide layer (metal oxide) 30 is for example, about or exactly 0.5 nm to about or exactly 2.5 nm, or, about or exactly 1.0 nm to about or exactly 1.1 nm. When the thickness of the metal oxide layer (metal oxide) 30 containing Cr₂O₃ is about or exactly 0.5 nm to about or exactly 2.5 nm, the magnetic properties of the magnetoresistive device 1 may be significantly improved. Additionally, in the case of a thickness of about or exactly 1.0 nm to about or exactly 1.1 nm, magnetic properties may be improved more significantly.

<First Nonmagnetic Layer (amorphous)>

The first nonmagnetic layer (amorphous) A10 is provided on the metal oxide layer (metal oxide) 30. The first nonmagnetic layer (amorphous) A10 contains a non-magnetic material. The first nonmagnetic layer (amorphous) A10 contains a material for dividing the rotational symmetry of the crystal with the rotation axis being the vertical direction (stacking direction) within the film of the first magnetic layer B10 and the SOT electrode layer 20. For example, the first magnetic layer B10 and the SOT electrode layer 20 have different rotational symmetries of crystal with the rotation axis being the stacking direction of each layer, or have different lattice constants (for example, significantly different lattice constants) in parallel directions within the film. For example, the first magnetic layer B10 includes a crystal structure with four-fold rotational symmetry with the direction perpendicular to the film surface (stacking direction) as the rotation axis, and the SOT electrode layer 20 includes a crystal structure with three-fold rotational symmetry with the stacking direction of each layer as the rotation axis. In some example embodiments, as the first nonmagnetic layer (amorphous) A10 is amorphous, the rotational symmetry of the crystal of the SOT electrode layer 20 and the first magnetic layer B10 is divided with the rotation axis being the stacking direction of each layer, and thus, the metal oxide layer (metal oxide) 30 in contact with the lower surface of the first nonmagnetic layer (amorphous) A10 may be crystal or amorphous. The crystals included in the SOT electrode layer 20 and the crystals included in the first magnetic layer (recording layer) B10 have different rotational symmetries of crystals with the rotation axis being the stacking direction of these layers.

The first nonmagnetic layer (amorphous) A10 at least partially contains amorphous materials. For example, the first nonmagnetic layer (amorphous) A10 contains a low-resistance amorphous material as a material. For example, the first nonmagnetic layer (amorphous) A10 may include at least partially a metal layer composed of amorphous. The first nonmagnetic layer (amorphous) A10 may also include a low-resistance material, half or more of which is amorphous. For example, half or more of the first nonmagnetic layer (amorphous) A10 may include an amorphous metal, such as about or exactly 50%, about or exactly 55%, about or exactly 60%, about or exactly 65%, about or exactly 70%, about or exactly 75%, about or exactly 80%, about or exactly 85%, about or exactly 90%, or about or exactly 95% of the first nonmagnetic layer (amorphous) A10 may include an amorphous metal.

The first nonmagnetic layer (amorphous) A10 may include Ta as a material, for example.

In some example embodiments, the first nonmagnetic layer (amorphous) A10 is not limited to containing Ta as long as it contains at least partially a low-resistance, amorphous material. For example, the first nonmagnetic layer (amorphous) A10 may include, as a material, at least one of a single transition metal, an alloy of transition metals, a compound of a transition metal and a semimetal, a transition metal nitride, a transition metal oxide, and/or a B—C—N based material. For example, the first nonmagnetic layer (amorphous) A10 may also include a single transition metal such as Ta, W and hafnium (Hf), an alloy of transition metals such as Ta—Cu and the like, or a compound of a transition metal such as Ta, W, Hf, molybdenum (Mo), niobium (Nb) or the like and a semimetal such as boron (B), carbon (C), silicon (Si), germanium (Ge) or the like. In addition, the first nonmagnetic layer (amorphous) A10 may also include an amorphous thin film composed of a B—C—N material of transition metal nitrides or oxides such as zirconium nitride (ZrN) and titanium nitride (TiN) with relatively low resistivity, furthermore, diamond like carbon (DLC), boron nitride (BN), carbon nitride (CN), and/or the like.

The thickness of the first nonmagnetic layer (amorphous) A10 is, for example, about or exactly 0.8 nm to about or exactly 1.0 nm, and details will be described later.

### <First Magnetic Layer (Recording Layer)>

The first magnetic layer (recording layer) B10 is provided on the first nonmagnetic layer (amorphous) A10. The first magnetic layer (recording layer) B10 contains a magnetic material. The first magnetic layer (recording layer) B10 may contain a ferromagnetic material. The first magnetic layer (recording layer) B10 functions as a recording layer of the MTJ element. Accordingly, a spin-orbit torque is applied to the first magnetic layer (recording layer) B10 of the MTJ element in accordance with the current flowing through the SOT electrode layer 20. The first magnetic layer (recording layer) B10 may contain, for example, CoFeB as a material. Accordingly, the first magnetic layer (recording layer) B10 may include a crystal structure with four-fold rotational symmetry. In some example embodiments, the first magnetic layer (recording layer) B10 functions as a recording layer of the MTJ element, and the material thereof is not limited to containing CoFeB as long as it contains a crystal structure with four-fold rotational symmetry.

### <Second Nonmagnetic Layer>

The second nonmagnetic layer A20 is provided on the first magnetic layer (recording layer) B10. The second nonmagnetic layer A20 contains a non-magnetic material. The second nonmagnetic layer A20 functions as a tunnel barrier layer of the MTJ element. The second nonmagnetic layer A20 may include, for example, magnesium oxide (MgO) as a material, however, the second nonmagnetic layer A20 is not limited thereto. Accordingly, the second nonmagnetic layer A20 may include a crystal structure with four-fold rotational symmetry.

### <Second Magnetic Layer>

The second magnetic layer B20 is provided on the second nonmagnetic layer A20. The second magnetic layer B20 contains a magnetic material. The second magnetic layer B20 may include a ferromagnetic material. The second magnetic layer B20 functions as a reference layer for the MTJ element. The second magnetic layer B20 may include, for example, CoFeB as a material. Accordingly, the second magnetic layer B20 may include a cubic system. In some example embodiments, the second magnetic layer B20 functions as a reference layer of the MTJ element, and is not limited to containing the material of CoFeB as long as it contains a crystal structure with four-fold rotational symmetry.

### <Layered Structure>

The magnetoresistive device 1 of some example embodiments may include, for example, a SOT-MRAM element. In the magnetoresistive device 1, the metal oxide layer (metal oxide) 30 and the first nonmagnetic layer (amorphous) A10 are disposed between the SOT electrode layer 20 and the first magnetic layer (recording layer) B10. The metal oxide layer (metal oxide) 30 includes, for example, a metal oxide layer with a long spin diffusion length (for example, a spin diffusion length greater than a distance between the SOT electrode layer 20 and the first magnetic layer (recording layer) B10 may be a long spin diffusion length). The first nonmagnetic layer (amorphous) A10 contains a low-resistance material formed of amorphous. Accordingly, as illustrated below, the problems of SOT-MRAM with the SOT electrode layer 20 containing BiSb described above may be reduced or prevented.

For example, the structure of the magnetoresistive device 1 of some example embodiments has a layered structure including the insulating buffer layer/SOT electrode layer 20/metal oxide layer (metal oxide) 30/first nonmagnetic layer (amorphous) A10/first magnetic layer (recording layer) B10/second nonmagnetic layer A20/second magnetic layer B20 from the bottom, for example, on the base layer 10 including an interlayer insulating film such as silicon oxide or the like. The magnetoresistive device 1 of this structure is formed by, for example, lamination by a sputtering film deposition apparatus and patterning of an MTJ element. Patterning may be performed on the MTJ element and the first nonmagnetic layer (amorphous) A10.

BiSb contained in the SOT electrode layer 20, and Cr₂O₃ contained in the metal oxide layer (metal oxide) 30 are known that three-fold rotational symmetry is preferentially adopted. In some example embodiments, when the laminate constituting the MTJ element may have good MTJ element characteristics when performing a four-fold rotational symmetry. For example, the layer in contact with the upper surface of the first nonmagnetic layer (amorphous) A10 and the layer in contact with the lower surface of the first nonmagnetic layer (amorphous) A10 have different crystal structures. If the MTJ element of a four-fold rotational symmetry is formed directly on a layer of a three-fold rotational symmetry, the lower first magnetic layer (recording layer) B10 deteriorates under the influence of the layer of the three-fold rotational symmetry.

In some example embodiments, the first nonmagnetic layer (amorphous) A10 of the magnetoresistive device 1 is inserted between the metal oxide layer (metal oxide) 30 containing three-fold rotational symmetry such as Cr₂O₃ and the first magnetic layer (recording layer) B10 containing four-fold rotational symmetry such as CoFeB or the like. Accordingly, the three-fold rotationally symmetric metal oxide layer (metal oxide) 30 and the four-fold rotationally symmetric first magnetic layer (recording layer) B10 are divided on the top and bottom. Accordingly, the metal oxide layer (metal oxide) 30 and the first magnetic layer (recording layer) B10 may fully demonstrate respective characteristics.

In the device structure of the magnetoresistive device 1 having the SOT electrode layer 20 containing BiSb, the effect of using a stack of the metal oxide layer (metal oxide) 30 containing Cr₂O₃/first nonmagnetic layer (amorphous) A10 containing Ta will be experimentally clarified below. For example, a magnetoresistive device 1 having the following laminated structure is created. In this case, the numbers in parentheses ( ) indicate the thickness of each layer.

### [Sample 1]

Laminated Structure of Sapphire Substrate/BiSb (10 nm)/CrOx (1.0 nm)/Ta (0.8 nm)/CoFeB (0.9 nm)/MgO (2.0 nm)/Ta (2.0 nm)

As a result of annealing this sample at 250° C. for 60 minutes, a perpendicular magnetic anisotropy of about 1.7 kOe was obtained as an anisotropic magnetic field Hk.

Furthermore, as a result of measuring the spin Hall angle of the magnetoresistive device 1 using a second harmonic Hall measurement method, the magnetoresistive device 1 of some example embodiments may obtain a value of 2.8, which is about one order of magnitude larger than the case in which a heavy metal such as W or Ta is used in the SOT electrode layer.

In the subsequent experiment that investigated the film thickness dependence of CrOx (the formation method of BiSb was different), when the CrOx film thickness is increased from about or exactly 1.0 nm to about or exactly 2.5 nm, the spin hole angle decreases from about or exactly 2.5 to about or exactly 1.2. For example, an optimal film thickness of CrOx, which is a metal oxide film, is about or exactly 1 nm. For example, the film thickness of CrOx may be about or exactly 1 nm. In this manner, when the metal oxide layer (metal oxide) 30 contains Cr₂O₃, the magnetic properties of the magnetoresistive device 1 may be significantly improved. Additionally, when the thickness of the metal oxide layer (metal oxide) 30 containing Cr₂O₃ is about or exactly 1.0 nm to about or exactly 1.1 nm, the magnetic properties may be further significantly improved.

The spin diffusion length of CrOx, a non-magnetic material, is regarded as being long as several nm or more (for example, about or exactly 1 nm to about or exactly 15 nm). However, at present, it is regarded that as the film thickness increases 1 nm or more, attenuation of spin occurs, for example, compared to a current direction.

When the film thickness of Ta, an amorphous metal, is increased to about or exactly 0.8 nm or more (for example about or exactly 5 nm or about or exactly 10 nm), a significant decrease in the spin Hall angle is observed. In the case of Ta, which has a large atomic weight and a large spin-orbit interaction, the spin diffusion length is regarded as being shorter even though it is a non-magnetic metal. Therefore, the film thickness of the first nonmagnetic layer (amorphous) A10 may be about or exactly 1 nm or less (for example, about or exactly 0.5 nm or about or exactly 0.8 nm). For example, the thickness of the first nonmagnetic layer (A10) is 0.8 to 1.0 nm.

The metal oxide layer (metal oxide) 30 is an antiferromagnetic oxide film and has a significantly long spin diffusion length of about several tens to several hundred nm (for example, about or exactly 50 nm to about or exactly 500 nm, about or exactly 20 nm to about or exactly 700 nm, or about or exactly 70 nm to about or exactly 600 nm). Thus, the spin current generated in the SOT electrode layer 20 containing BiSb may not be attenuated, and may be transmitted to the first magnetic layer (recording layer) B10.

As a result, the magnetoresistive device 1 may provide a relatively large SOT to the first magnetic layer (recording layer) B10, and thus the magnetic properties may be improved.

In addition, the metal oxide layer (metal oxide) 30 has the effect of flattening the first magnetic layer (recording layer) B10 on the SOT electrode layer 20, in addition to alleviating the surface roughness of the SOT electrode layer 20 containing BiSb, which is difficult to flatten for sputtering film deposition. For example, by inserting the laminate of the metal oxide layer (metal oxide) 30/first nonmagnetic layer (amorphous) A10 between the SOT electrode layer 20 and the first magnetic layer (recording layer) B10, spin diffusion loss caused by the interface of the SOT electrode layer 20/first magnetic layer (recording layer) B10 may be reduced, and a large spin Hall angle may be obtained.

Furthermore, the metal oxide layer (metal oxide) 30 acts as an element diffusion barrier between the SOT electrode layer 20 and the first magnetic layer (recording layer) B10, and may suppress mutual spread as described above. Since this diffusion barrier is stable even during high-temperature annealing, not only mutual diffusion during film formation but also mutual diffusion during high-temperature annealing to improve magnetic properties may be suppressed. Due to the effect of flattening the first magnetic layer (recording layer) B10 and the effect of suppressing mutual diffusion, the magnetoresistive device 1 of some example embodiments may obtain magnetic properties such as the good perpendicular magnetic anisotropy and the like described above.

Additionally, Cr₂O₃ is an insulator with a band gap of about or exactly 3.2 eV, and thus, the flow of the switching current from the SOT electrode layer 20 containing BiSb to the first magnetic layer (recording layer) B10 may be suppressed. As a result, the magnetoresistive device 1 of some example embodiments may confine the switching current within the SOT electrode layer 20 containing BiSb, and may perform SOT switching with relatively higher efficiency.

In addition, as an insertion effect of the lamination of the metal oxide layer (metal oxide) 30/first nonmagnetic layer (amorphous) A10, the first nonmagnetic layer (amorphous) A10 may improve the wettability of the metallic film on the metal oxide layer (metal oxide) 30, and flat film formation may be obtained.

Furthermore, the amorphous metal of Ta absorbs B of adjacent CoFeB and promotes crystallization of CoFeB, and as a result, the magnetic properties of MTJ elements containing CoFeB/MgO/CoFeB may be improved.

In SOT-MRAM, to perform switching with low current consumption, it is desirable to select a material for the SOT electrode layer 20 that may obtain a relatively large spin Hall angle. The SOT electrode layer 20 containing BiSb according to some example embodiments may obtain a much larger spin hole angle than the SOT electrode layer containing heavy metals, while problems which hindered practical use, such as surface roughening and mutual diffusion caused by sputtering film deposition may be improved.

In some example embodiments, the magnetoresistive device 1 may include the metal oxide layer (metal oxide) 30 having a sufficiently long spin diffusion length and also acting as a diffusion barrier inserted between the SOT electrode layer 20 containing BiSb and the first magnetic layer (recording layer) B10. Furthermore, in the magnetoresistive device 1 of some example embodiments, the crystal structure of the upper and lower layers in divided by the first nonmagnetic layer (amorphous) A10.

Accordingly, causes of deterioration of SOT switching characteristics may be excluded or reduced, and thus magnetic characteristics including switching characteristics may be improved.

### Modified Example 1

FIGS. 1 and 2 described above illustrate the magnetoresistive device 1 having a BiSb bottom structure in which the SOT electrode layer 20 containing BiSb is provided in the lower side. However, the magnetoresistive device 1 may have a BiSb top structure in which the entire structure is upside down and the SOT electrode layer 20 is disposed in the upper side.

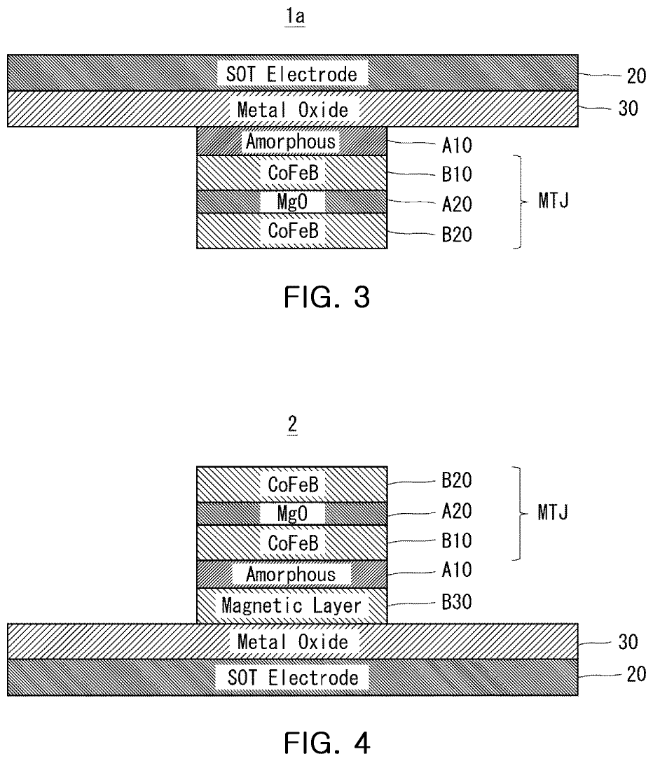

FIG. 3 is a cross-sectional view illustrating Embodiment 1 of a magnetoresistive device 1a according to some example embodiments. As illustrated in FIG. 3, the magnetoresistive device 1a may include a second magnetic layer B20, a second nonmagnetic layer A20, a first magnetic layer (recording layer) B10, a first nonmagnetic layer (amorphous) A10, a metal oxide layer (metal oxide) 30, and an SOT electrode layer 20 from the bottom. Additionally, the magnetoresistive device 1a may also be formed from the bottom in this order. Even with this structure, the same effect as the magnetoresistive device 1 described above may be obtained.

### Embodiment 2

Next, a magnetoresistive device according to Embodiment 2 will be described. FIG. 4 is a cross-sectional view illustrating Embodiment 2 of a magnetoresistive device according to some example embodiments. As illustrated in FIG. 4, the magnetoresistive device 2 of some example embodiments further includes a third magnetic layer B30 in addition to the structure of the magnetoresistive device 1 of the first embodiment. The third magnetic layer B30 may also be referred to as a magnetic layer B30. The third magnetic layer (magnetic layer) B30 is provided between the metal oxide layer (metal oxide) 30 and the first nonmagnetic layer (amorphous) A10. For example, for example, between the SOT electrode layer 20 containing BiSb and the first magnetic layer (recording layer) B10 containing CoFeB, a metal oxide layer (metal oxide) 30/third magnetic layer (magnetic layer) B30/first nonmagnetic layer (amorphous) A10 is inserted.

### <Third Magnetic Layer>

The third magnetic layer (magnetic layer) B30 is provided on the metal oxide layer (metal oxide) 30. Accordingly, the first nonmagnetic layer (amorphous) A10 is provided on the third magnetic layer (magnetic layer) B30. Accordingly, the third magnetic layer (magnetic layer) B30 is disposed between the metal oxide layer (metal oxide) 30 and the first nonmagnetic layer (amorphous) A10.

The third magnetic layer (magnetic layer) B30 contains a magnetic material. The third magnetic layer (magnetic layer) B30 may contain a ferromagnetic material. The third magnetic layer (magnetic layer) B30 is magnetically coupled to the first magnetic layer (recording layer) B10. Accordingly, the first magnetic layer (recording layer) B10 and the third magnetic layer (magnetic layer) B30 function as a recording layer of the MTJ element as a whole. The third magnetic layer (magnetic layer) B30 may contain, for example, Co as a material. Accordingly, the third magnetic layer (magnetic layer) B30 may include three-fold rotational symmetry of the hexagonal system. In some example embodiments, the third magnetic layer (magnetic layer) B30 is not limited to containing Co as a material, as long as it is a magnetic layer containing three-fold rotational symmetry, and may also contain a Co—Pt alloy, and/or the like.

### <Layered Structure>

The structure of the magnetoresistive device 2 of some example embodiments is a layered structure including an insulating buffer layer/SOT electrode layer 20/metal oxide layer (metal oxide) 30/third magnetic layer (magnetic layer) B30/first nonmagnetic layer (amorphous) A10/first magnetic layer (recording layer) B10/second nonmagnetic layer A20/second magnetic layer B20 from the bottom, for example, on the base layer 10 including an interlayer insulating film such as silicon oxide. The magnetoresistive device 2 of this structure is formed, for example, by lamination by a sputter film forming apparatus and patterning an MTJ element portion. The patterning may be performed on the MTJ element portion, the first nonmagnetic layer (amorphous) A10 and the third magnetic layer (magnetic layer) B30.

Further, in some example embodiment of the structure of the magnetoresistive device 2, the crystal systems are different in the layers above and below the first nonmagnetic layer (amorphous) A10. For example, a third magnetic layer (magnetic layer) B30 having three-fold rotational symmetry is disposed on the lower surface of the first nonmagnetic layer (amorphous) A10. The upper and lower layers of the first nonmagnetic layer (amorphous) A10 may respectively have an optimal crystal structure suited to functions thereof. Thus, the magnetoresistive device 2 may improve magnetic properties thereof.

The magnetoresistive device 2 of some example embodiments has the following features as a different characteristic from the magnetoresistive device 1 described above. For example, the third magnetic layer (magnetic layer) B30 on the metal oxide layer (metal oxide) 30 is magnetically coupled to the first magnetic layer (recording layer) B10. Accordingly, the first magnetic layer (recording layer) B10 and the third magnetic layer (magnetic layer) B30 function as a recording layer of the MTJ element as a whole. This magnetically coupled two-layer recording layer increases the overall volume, thereby improving thermal disturbance resistance.

In addition, as the interfacial magnetic anisotropy of the interface between the metal oxide layer (metal oxide) 30 and the third magnetic layer (magnetic layer) B30 may be used, the perpendicular magnetic anisotropy of the MTJ element may be improved, and further, the thermal disturbance resistance may be further improved. Furthermore, equally to the layer having three-fold rotational symmetry, such as the SOT electrode layer 20 and the metal oxide layer (metal oxide) 30, the third magnetic layer (magnetic layer) B30 having three-fold rotational symmetry is directly bonded. Accordingly, spin loss at the interface may be suppressed. In this manner, the magnetoresistive device 2 of some example embodiments may further improve magnetic properties thereof.

### (Modified Example)

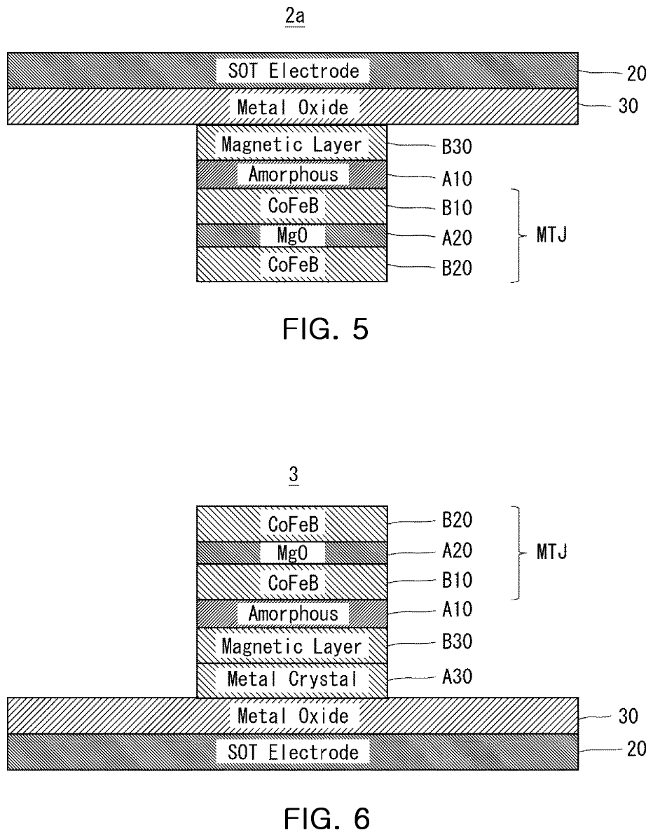

FIG. 5 is a cross-sectional view illustrating Embodiment 2 of a magnetoresistive device according to some example embodiments. As illustrated in FIG. 5, the magnetoresistive device 2a according to the modified example may have a BiSb top structure. For example, the magnetoresistive device 2a may include a second magnetic layer B20, a second nonmagnetic layer A20, a first magnetic layer (recording layer) B10, a first nonmagnetic layer (amorphous) A10, a third magnetic layer (magnetic layer) B30, a metal oxide layer (metal oxide) 30, and an SOT electrode layer 20 from the bottom. Additionally, the magnetoresistive device 2a may also be formed from the bottom in this order. Even with this structure, the same effect as the magnetoresistive device 2 of Embodiment 2 described above may be obtained.

### Embodiment 3

Next, the magnetoresistive device according to Embodiment 3 will be described. FIG. 6 is a cross-sectional view illustrating Embodiment 3 of a magnetoresistive device according to some example embodiments. As illustrated in FIG. 6, the magnetoresistive device 3 of some example embodiments further includes a third nonmagnetic layer A30, in addition to the structure of the magnetoresistive device 2 of the second embodiment. The third nonmagnetic layer A30 is referred to as metal crystalline structure A30. The third nonmagnetic layer (metal crystal) A30 is provided between the metal oxide layer (metal oxide) 30 and the third magnetic layer (magnetic layer) B30. For example, a metal oxide layer (metal oxide) 30/third nonmagnetic layer (metal crystal) A30/third magnetic layer (magnetic layer) B30/first nonmagnetic layer (amorphous) A10 is inserted between the SOT electrode layer 20 containing BiSb and the first magnetic layer (recording layer) B10 containing CoFeB.

### <Third Nonmagnetic Layer>

The third nonmagnetic layer (metal crystal) A30 is provided on the metal oxide layer (metal oxide) 30. Accordingly, the third magnetic layer (magnetic layer) B30 is provided on the third nonmagnetic layer (metal crystal) A30. Therefore, the third nonmagnetic layer (metal crystal) A30 is disposed between the metal oxide layer (metal oxide) 30 and the third magnetic layer (magnetic layer) B30.

The third nonmagnetic layer (metal crystal) A30 may contain a non-magnetic material. The third nonmagnetic layer (metal crystal) A30 may also contain metal as a material. For example, the third nonmagnetic layer (metal crystal) A30 may include a crystalline metal layer. The third nonmagnetic layer (metal crystal) A30 has a crystal structure that alleviates the mismatch between the crystal lattices of the metal oxide layer (metal oxide) 30 and the third magnetic layer (magnetic layer) B30, and functions as a buffer layer that alleviates mismatch in the crystal lattice. Therefore, the third nonmagnetic layer (metal crystal) A30 may reduce spin loss during spin injection from the SOT electrode layer 20 to the third magnetic layer (magnetic layer) B30.

Trigonal BiSb, having three-fold rotational symmetry, exhibits a lattice constant of about or exactly 4.31 Å to about or exactly 4.55 Å. As the metal oxide layer (metal oxide) 30 formed on the SOT electrode layer 20 containing BiSb, for example, Cr₂O₃ is a hexagonal system with three-fold rotational symmetry and has a lattice constant of about or exactly 4.96 Å. At this point, Cr₂O₃ crystallizes on BiSb with a lattice mismatch of about or exactly 10%.

In this case, since the lattice constant of Co in the hexagonal system with three-fold rotational symmetry is about 2.51 or exactly Å, when Cr₂O₃ is not lattice relaxed, it is regarded that the crystal grows in a 2-fold cycle with a lattice mismatch of about or exactly 10%. To alleviate (or reduce) this lattice mismatch, as a material of the third nonmagnetic layer (metal crystal) A30, a material having three-fold rotational symmetry and also having a lattice constant between the lattice constant of BiSb and twice the lattice constant of Co may be used. Accordingly, the third nonmagnetic layer (metal crystal) A30 may include TiCr₂ as this material. TiCr₂ is an intermetallic compound with hexagonal three-fold rotational symmetry and a lattice constant of about or exactly 4.84 Å. In some example embodiments, the third nonmagnetic layer (metal crystal) A30 is not limited to including TiCr₂ as long as it is a material that has a three-fold rotational symmetry crystal structure and a lattice constant in the middle of twice the lattice constant of Co.

In this case, due to the insertion of the third nonmagnetic layer (metal crystal) A30, it is regarded that the bond between the third magnetic layer (magnetic layer) B30 and the metal oxide layer (metal oxide) 30 will be lost. For this reason, there is concern about a decrease in magnetic anisotropy utilizing the interfacial magnetic anisotropy between the third magnetic layer (magnetic layer) B30 and the metal oxide layer (metal oxide) 30. In that case, a Pt layer may be inserted into the lower surface of the third magnetic layer (magnetic layer) B30. Alternatively, as the third magnetic layer (magnetic layer) B30, a Co₃Pt layer is formed. In this manner, when the third magnetic layer (magnetic layer) B30 is formed of a Co—Pt alloy with three-fold rotational symmetry and bulk perpendicular magnetic anisotropy, vertical magnetic anisotropy may be increased.

However, the main effect of the third nonmagnetic layer (metal crystal) A30 in some example embodiments is to function as a buffer layer that alleviates lattice mismatch. However, the third nonmagnetic layer (metal crystal) A30 has the effect of improving the wettability of the third magnetic layer (magnetic layer) B30 formed on the metal oxide layer (metal oxide) 30.

For example, it is known that Co contained in the third magnetic layer (magnetic layer) B30 generally has a large surface energy and reduces wettability when forming a film on an oxide film. In this case, when at least one metal with good wettability, such as Cr or Ti, is formed into a thin film of about or exactly 1 nm or less and then Co is formed into a film, Co may be formed flatly. Therefore, to implement this film formation, the thickness of the third nonmagnetic layer (metal crystal) may be greater than 0 nm and may be less than about or exactly 1.0 nm. In this manner, the magnetoresistive device 3 further includes a third nonmagnetic layer (metal crystal) A30 provided between the metal oxide layer (metal oxide) 30 and the third magnetic layer (magnetic layer) B30. The surface energy of the third magnetic layer (magnetic layer) B30 formed on the third nonmagnetic layer (metal crystal) is smaller than the surface energy of the third magnetic layer (magnetic layer) B30 when formed on the metal oxide layer (metal oxide) 30. Accordingly, in the third magnetic layer (magnetic layer) B30 formed on the third nonmagnetic layer (metal crystal), island-like growth is suppressed and flatness is improved.

In this case, thin films such as Cr and Ti may not show a clear orientation due to a different crystal system or lattice constant from the metal oxide layer (metal oxide) 30 such as Cr₂O₃. However, even if the crystallinity of the third magnetic layer (magnetic layer) B30 containing Co is reduced due to this, magnetization may be reversed by the spin current injected from the SOT electrode layer 20 containing BiSb.

### <Layered Structure>

The structure of the magnetoresistive device 3 of some example embodiments is a layered structure including an insulating buffer layer/SOT electrode layer 20/metal oxide layer (metal oxide) 30/third nonmagnetic layer (metal crystal) A30/third magnetic layer (magnetic layer) B30/first nonmagnetic layer (amorphous) A10/first magnetic layer (recording layer) B10/second nonmagnetic layer A20/second magnetic layer B20, from the bottom, for example, on the base layer 10 including an interlayer insulating film such as silicon oxide. The magnetoresistive device 3 of this structure is laminated, for example, by a sputter film forming apparatus and formed by patterning the MTJ element portion. Patterning may be performed on the MTJ element portion, the first nonmagnetic layer (amorphous) A10, the third magnetic layer (magnetic layer) B30, and the third nonmagnetic layer (metal crystal) A30.

Also in the structure of the magnetoresistive device 3, the crystal systems are different in the layers above and below the first nonmagnetic layer (amorphous) A10. The upper and lower layers of the first nonmagnetic layer (amorphous) A10 may respectively have a crystal structure (for example, an optimal crystal structure) suited to functions thereof. Therefore, the magnetoresistive device 3 may improve magnetic properties thereof.

The magnetoresistive device 3 of some example embodiments has the following features as a different feature from the magnetoresistive device 2 described above. For example, the third nonmagnetic layer (metal crystal) A30 is a buffer layer to alleviate the difference in crystal structure or lattice mismatch between the metal oxide layer (metal oxide) 30 and the third magnetic layer (magnetic layer) B30, and thus, spin loss during spin injection from the SOT electrode layer 20 to the third magnetic layer (magnetic layer) B30 may be reduced. From this, the magnetic properties of the magnetoresistive device 3 may also be improved by the configuration of some example embodiments.

### Modified Example

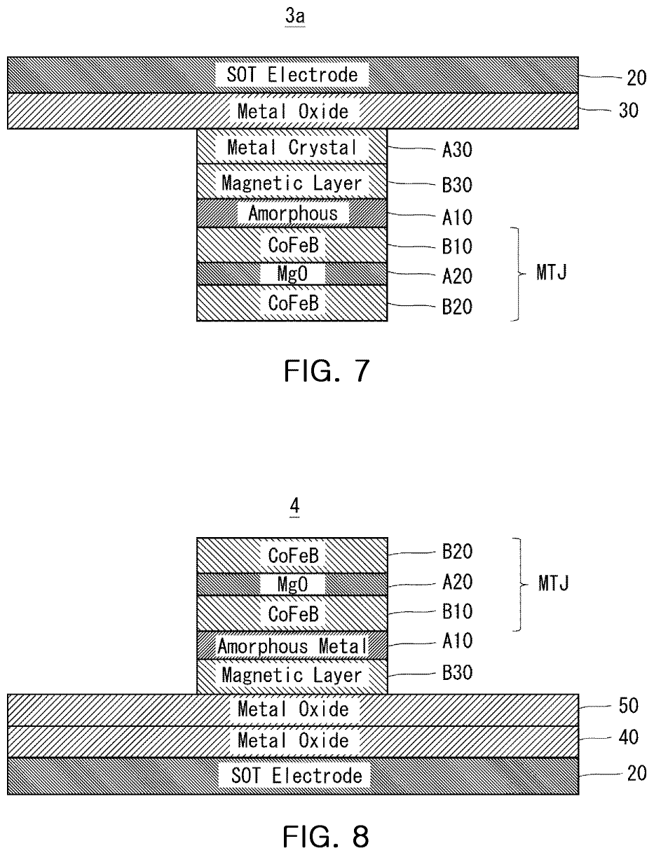

FIG. 7 is a cross-sectional view illustrating Embodiment 3 of a magnetoresistive device according to some example embodiments. As illustrated in FIG. 7, the magnetoresistive device 3a according to the modified example has a BiSb top structure. For example, the magnetoresistive device 3a may also include a second magnetic layer B20, a second nonmagnetic layer A20, a first magnetic layer (recording layer) B10, a first nonmagnetic layer (amorphous) A10, a third magnetic layer (magnetic layer) B30, a third nonmagnetic layer (metal crystal) A30, a metal oxide layer (metal oxide) 30, and an SOT electrode layer 20, from the bottom. Additionally, the magnetoresistive device 3a may also be formed from the bottom in this order. Even with this structure, the same effect as the magnetoresistive device 3 of Embodiment 3 described above may be obtained.

### Embodiment 4

Next, a magnetoresistive device according to Embodiment 4 will be described. FIG. 8 is a cross-sectional view illustrating Embodiment 4 of a magnetoresistive device 4 according to some example embodiments. As illustrated in FIG. 8, the magnetoresistive device 4 of some example embodiments includes a first metal oxide layer (metal oxide) 40 and a second metal oxide layer (metal oxide) 50, instead of the metal oxide layer (metal oxide) 30 in the magnetoresistive device 2 of Embodiment 2.

For example, the metal oxide layer (metal oxide) 30 includes the first metal oxide layer (metal oxide) 40 and the second metal oxide layer (metal oxide) 50. The first metal oxide layer (metal oxide) 40 is provided between the SOT electrode layer 20 and the second metal oxide layer (metal oxide) 50.

The second metal oxide layer (metal oxide) 50 is provided between the first metal oxide layer (metal oxide) 40 and the third magnetic layer (magnetic layer) B30.

### <First Metal Oxide Layer (Metal Oxide)>

The first metal oxide layer (metal oxide) 40 is provided on the SOT electrode layer 20. The first metal oxide layer (metal oxide) 40 may have the same function as the metal oxide layer (metal oxide) 30. Additionally, the first metal oxide layer (metal oxide) 40 may have the same material and crystal structure as the metal oxide layer 30 (metal oxide). For example, the first metal oxide layer (metal oxide) 40 may include metal oxide as a material. Additionally, the first metal oxide layer (metal oxide) 40 may include a metal oxide with three-fold rotational symmetry. For example, the first metal oxide layer (metal oxide) 40 may include Cr₂O₃ as a material. In some example embodiments, the first metal oxide layer (metal oxide) 40 is not limited to including the same material and crystal structure as the metal oxide layer 30 (metal oxide) as long as it includes a metal oxide different from the second metal oxide layer (metal oxide) 50 as a material.

### <Second Metal Oxide Layer (Metal Oxide)>

The second metal oxide layer (metal oxide) 50 is provided on the first metal oxide layer (metal oxide) 40. Accordingly, the third magnetic layer (magnetic layer) B30 is provided on the second metal oxide layer (metal oxide) 50.

The second metal oxide layer (metal oxide) 50 may include, for example, a material that induces high interfacial magnetic anisotropy at the interface with the third magnetic layer (magnetic layer) B30. The material may be, for example, amorphous oxides or may be selected from among polycrystalline oxides. The method of forming the second metal oxide layer (metal oxide) 50 may be selected from various methods such as natural oxidation, plasma oxidation, direct sputtering of oxide, and the like.

The second metal oxide layer (metal oxide) 50 may include at least one of aluminum oxide, tantalum oxide, magnesium oxide, ruthenium oxide, hafnium oxide, and/or chromium oxide as a material. By including these materials, the effect of inducing high interfacial magnetic anisotropy may be obtained.

In addition, the second metal oxide layer (metal oxide) 50 matches the crystal system or lattice constant between the third magnetic layer (magnetic layer) B30 with three-fold rotational symmetry and the first metal oxide layer (metal oxide) 40 with three-fold rotational symmetry, thereby performing more effective spin injection. However, as in the above case, in the second metal oxide layer (metal oxide) 50, even in case of containing an amorphous material or when the crystal system is different from the third magnetic layer (magnetic layer) B30 and the first metal oxide layer (metal oxide) (40), as a magnetic material layer, magnetization may be reversed by the spin current injected from the SOT electrode layer 20.

### <Layered Structure>

The structure of the magnetoresistive device 4 of some example embodiments is a layered structure including an insulating buffer layer/SOT electrode layer 20/first metal oxide layer (metal oxide) 40/second metal oxide layer (metal oxide) 50/third magnetic layer (magnetic layer) B30/first nonmagnetic layer (amorphous) A10/first magnetic layer (recording layer) B10/second nonmagnetic layer A20/second magnetic layer B20, from the bottom, on the base layer 10 containing an interlayer insulating film such as silicon oxide. The magnetoresistive device 4 of this structure is laminated, for example, by a sputter film forming apparatus and formed by patterning the MTJ element. Patterning may be performed on the MTJ element, the first nonmagnetic layer (amorphous) A10 and the third magnetic layer (magnetic layer) B30.

Also in the structure of the magnetoresistive device 4, the crystal systems are different in the layers above and below the first nonmagnetic layer (amorphous) A10. The upper and lower layers of the first nonmagnetic layer (amorphous) A10 may respectively have a crystal structure (for example, an optimal crystal structure) suited to functions thereof. As a result, the magnetoresistive device 4 may improve magnetic properties thereof.

The magnetoresistive device 4 of some example embodiments has different functions in the first metal oxide layer (metal oxide) 40 and the second metal oxide layer (metal oxide) 50. For example, the first metal oxide layer (metal oxide) 40 contains a material that increases spin injection efficiency from the SOT electrode layer 20 containing BiSb. Furthermore, the first metal oxide layer (metal oxide) 40 is a material that is difficult to oxidize BiSb during film formation. In some example embodiments, the second metal oxide layer (metal oxide) 50 is a material that induces high interfacial magnetic anisotropy at the interface with the third magnetic layer (magnetic layer) B30. Thus, the magnetoresistive device 4 of some example embodiments may improve magnetic properties thereof.

### Modified Example

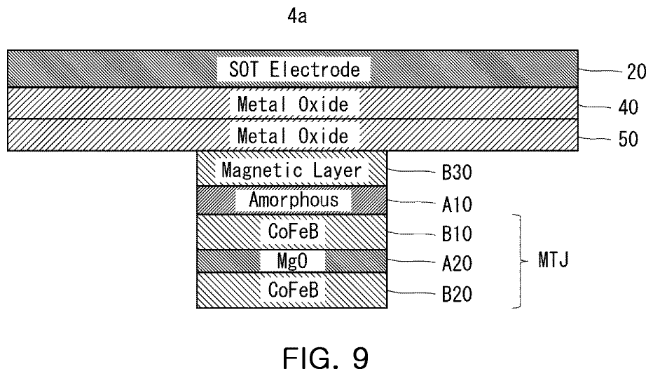

FIG. 9 is a cross-sectional view illustrating Embodiment 4 of a magnetoresistive device according to some example embodiments. As illustrated in FIG. 9, the magnetoresistive device 4a according to the modified example may have a BiSb top structure. For example, the magnetoresistive device 4a may also include a second magnetic layer B20, a second nonmagnetic layer A20, a first magnetic layer (recording layer) B10, a first nonmagnetic layer (amorphous) A10, a third magnetic layer (magnetic layer) B30, a second metal oxide layer (metal oxide) 50, a first metal oxide layer (metal oxide) 40, and an SOT electrode layer 20, from the bottom. Additionally, the magnetoresistive device 4a may also be formed from the bottom in this order. Even with this structure, the same effect as the magnetoresistive device 4 in the above-described embodiment 4 may be obtained.

### Embodiment 5

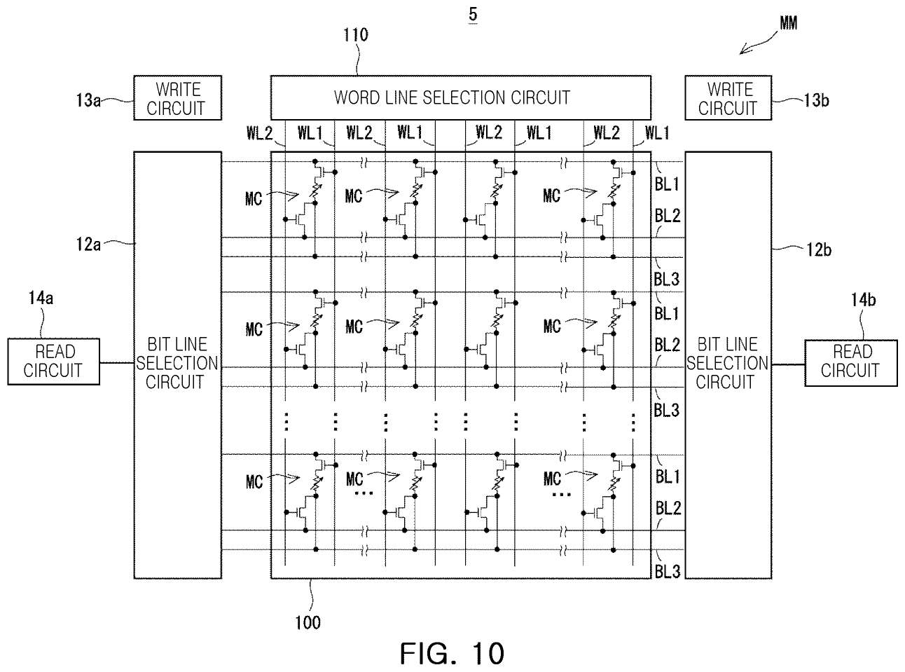

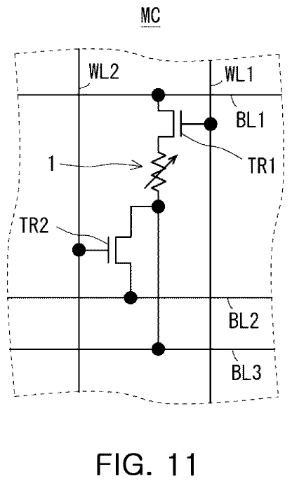

Next, Embodiment 5 will be described. Some example embodiments is a semiconductor device including any one of the magnetoresistive devices 1 to 4. FIGS. 10 and 11 are circuit diagrams illustrating Embodiment 5 of a semiconductor device 5 according to some example embodiments. As illustrated in FIGS. 10 and 11, the semiconductor device 5 of some example embodiments may include a magnetic memory (MM) or a memory cell MC.

As illustrated in FIG. 10, a magnetic memory (MM) is provided with a memory cell array 100 in which memory cells MC are disposed in an array, two word lines WL1 and WL2 provided corresponding to the memory cells MC disposed in the same column direction, three bit lines BL1, BL2 and BL3 provided in response to memory cells MC disposed in the same row direction, a word line selection circuit 110, bit line selection circuits 12a and 12b, write circuits 13a and 13b, and read circuits 14a and 14b.

As illustrated in FIG. 11, each memory cell MC is provided with one of the above-described magnetoresistive devices 1 to 4 and 1a to 4a and transistors TR1 and TR2. In this case, the case in which the magnetoresistive device 1 is used is described as an example.

In the memory cell MC, the second magnetic layer B20 of the magnetoresistive device 1 is connected to one side of source and drain of the transistor TR1. The other side of the source and drain of the transistor TR1 is connected to a bit line BL1, and a gate is connected to a word line WL1. One end of the SOT electrode layer 20 is connected to one side of the source and drain of the transistor TR2, and the other end thereof is connected to the bit line BL3. The side of source and drain of the transistor TR2 is connected to a bit line BL2, and a gate thereof is connected to a word line WL2.

### (Writing Operation)

Next, writing to the memory cell MC will be described. First, the word line selection circuit 110 applies a high level potential to the word line WL2 to which the gate of the transistor TR2 is connected, such that the transistor TR2 of the memory cell MC to perform writing is turned on. At or about this time, the transistor TR2 in other memory cells MC in the column to which the memory cell MC belongs is also turned on. However, a low-level potential is applied to the word line WL1 connected to the gate of the transistor TR1 in the memory cell MC and the word lines WL1 and WL2 corresponding to other columns, respectively.

Subsequently, bit lines BL2 and BL3 connected to the memory cell MC performing writing are selected by the bit line selection circuits 12a and 12b. In addition, a write current flows to the selected bit lines BL2 and BL3 in a direction from one side of the bit line selection circuits 12a and 12b to the other side thereof, by the write circuits 13a and 13b. By this write current, the magnetization direction of the first magnetic layer (recording layer) B10 of the magnetoresistive device 1 may become magnetization inversion, and writing is performed. In some example embodiments, when a write current flows in a direction from the other side of the bit line selection circuit 12a and the bit line selection circuit 12b to one side thereof, the magnetization direction of the first magnetic layer (recording layer) B10 of the magnetoresistive device 1 may become magnetization inversion to the direction opposite to the above-mentioned case, and writing is performed.

### (Read Operation)

Next, the read operation from the memory cell MC will be described. First, a high level potential is applied to the word line WL1 connected to the memory cell MC to read, and the transistor TR1 in the memory cell MC is turned on. At or about this time, the transistor TR1 in other memory cells MC in the column to which the memory cell MC belongs is also turned on. However, a low level potential is applied to the word line WL2 connected to the gate of the transistor TR2 in the memory cell MC and the word lines WL1 and WL2 corresponding to other columns, respectively.

Subsequently, bit lines BL1 and BL3 connected to the memory cell MC performing reading are selected by the bit line selection circuits 12a and 12b. In addition, a read current flows to these selected bit lines BL1 and BL3 in a direction from one side of the bit line selection circuits 12a and 12b to the other side thereof, by the read circuits 14a and 14b. At or about this time, for example, by detecting the voltage between the selected bit lines BL1 and BL3 by the read circuits 14a and 14b, detecting may be performed whether the magnetization directions are parallel to each other (same direction) or are antiparallel to each other (reverse direction) between the first magnetic layer (recording layer) B10 and the second magnetic layer (reference layer) B20 of the magnetoresistive device 1. For example, reading may be performed.

Since the semiconductor device 5 of some example embodiments includes the magnetoresistive device 1 described above, the magnetic properties may be improved, and writing and reading operations may be improved.

In some example embodiments, the present inventive concepts are not limited to the above-described example embodiments, and appropriate changes may be made without departing from the spirit. For example, combining respective configurations of Embodiments 1 to 5 are also within the scope of the technical ideas of the present inventive concepts.

As set forth above, according to some example embodiments, a magnetoresistive device and a semiconductor device in which switching characteristics may be improved may be provided.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While some example embodiments have been illustrated and described above, it will be apparent to those skilled in the art that modifications and variations could be made without departing from the scope of the present inventive concepts as defined by the appended claims.

What is claimed is:

1. A magnetoresistive device comprising:
a spin orbit torque (SOT) electrode layer;
a metal oxide layer on the SOT electrode layer;
a first nonmagnetic layer on the metal oxide layer; and
a magnetic tunnel junction element including
a first magnetic layer on the first nonmagnetic layer,
a second nonmagnetic layer on the first magnetic layer, and
a second magnetic layer on the second nonmagnetic layer,
the SOT electrode layer including BiSb,
the metal oxide layer including metal oxide,
the first nonmagnetic layer at least partially including an amorphous material, and
a crystal included in the SOT electrode layer and a crystal included in the first magnetic layer have different rotational symmetries to a stacking direction thereof.

2. The magnetoresistive device of claim 1, further comprising a third magnetic layer between the metal oxide layer and the first nonmagnetic layer,
wherein the third magnetic layer is magnetically coupled to the first magnetic layer.

3. The magnetoresistive device of claim 2, further comprising a third nonmagnetic layer between the metal oxide layer and the third magnetic layer,
wherein the third nonmagnetic layer has a crystal structure alleviating mismatch between crystal lattices of the metal oxide layer and the third magnetic layer.

4. The magnetoresistive device of claim 2, further comprising a third nonmagnetic layer between the metal oxide layer and the third magnetic layer,
wherein a surface energy of the third magnetic layer on the third nonmagnetic layer is smaller than a surface energy of the third magnetic layer on the metal oxide layer.

5. The magnetoresistive device of claim 2, wherein the metal oxide layer includes a first metal oxide layer and a second metal oxide layer,
wherein the first metal oxide layer includes a metal oxide different from a metal oxide of the second metal oxide layer.

6. The magnetoresistive device of claim 1, wherein the metal oxide layer includes a metal oxide having a spin diffusion length longer than a distance between the SOT electrode layer and the first magnetic layer.

7. The magnetoresistive device of claim 1, wherein
the first magnetic layer includes a crystal with a four-fold rotational symmetry, and
the SOT electrode layer includes a crystal with three-fold rotational symmetry.

8. The magnetoresistive device of claim 1, wherein the metal oxide layer contains Cr₂O₃.

9. The magnetoresistive device of claim 8, wherein a thickness of the metal oxide layer is 0.5 nm to 2.5 nm.

10. The magnetoresistive device of claim 1, wherein the first nonmagnetic layer at least partially includes an amorphous metal.

11. The magnetoresistive device of claim 1, wherein the first nonmagnetic layer includes at least one of a single transition metal, an alloy of transition metals, a compound of a transition metal and a semimetal, a transition metal nitride, a transition metal oxide, or a B—C—N based material.

12. The magnetoresistive device of claim 10, wherein a thickness of the first nonmagnetic layer is 0.8 nm to 1.0 nm.

13. The magnetoresistive device of claim 2, wherein the third magnetic layer includes at least one of Co or a Co—Pt alloy.

14. The magnetoresistive device of claim 2, wherein the third magnetic layer includes a crystal with three-fold rotational symmetry with the stacking direction, as the rotation axis.

15. The magnetoresistive device of claim 3, wherein the third nonmagnetic layer includes a metal.

16. The magnetoresistive device of claim 3, wherein the third nonmagnetic layer includes TiCr₂.

17. The magnetoresistive device of claim 15, wherein a thickness of the third nonmagnetic layer is greater than 0 nm and less than 1.0 nm.

18. The magnetoresistive device of claim 3, wherein the third nonmagnetic layer includes the crystal with three-fold rotational symmetry with the stacking direction being the rotation axis.

19. The magnetoresistive device of claim 5, wherein
the first metal oxide layer includes Cr₂O₃ as a material, and
the second metal oxide layer includes at least one of aluminum oxide, tantalum oxide, magnesium oxide, ruthenium oxide, hafnium oxide, or chromium oxide.

20. The magnetoresistive device of claim 1, further comprising a base layer,
wherein the SOT electrode layer is on the base layer.
